(19) United States
(12) Patent Application Publication
(10) Pub. No.: US 2026/0092996 A1
(43) Pub. Date: Apr. 2, 2026

(54) POLE PIECE

(71) Applicant: NANALYSIS CORP., Calgary, Alberta (CA)

(72) Inventors: Neal GALLAGHER, Calgary, Alberta (CA); Garett LESKOWITZ, Calgary, Alberta (CA)

(73) Assignee: NANALYSIS CORP., Calgary, Alberta (CA)

(21) Appl. No.: 19/111,650

(22) PCT Filed: Sep. 15, 2023
(86) PCT No.: PCT/CA2023/051234

§ 371 Date: Mar. 13, 2025

Related U.S. Application Data
(60) Provisional application No. 63/407,483, filed on Sep. 16, 2022.

(51) Int. Cl. G01R 33/3873; H01F 7/02

(52) U.S. Cl. CPC G01R 33/3873; H01F 7/0278

(57) ABSTRACT

Described are a pole piece assembly for use in a Halbach-type magnet configuration, a magnetic resonance device comprising the pole piece assembly, and a method for shimming a magnetic field using the pole piece assembly. The pole piece comprising a rear face, a front face S, and ends separated by a first distance defining a length of said pole piece assembly along a first axis extending between said ends, said pole piece assembly being configured for insertion into an interior of the Halbach-type magnet configuration along said first axis, wherein a surface of the front face S is curved, and wherein a curvature of the front face is mathematically defined for shimming the magnetic field generated by the magnet configuration.

### CROSS-REFERENCE TO RELATED APPLICATIONS

This application is a National Stage Application of PCT/CA2023/051234, filed Sep. 15, 2023, which claims benefit of priority to U.S. Provisional Patent Application No. 63/407,483 filed on Sep. 16, 2022, and which applications are incorporated herein by reference. To the extent appropriate, a claim of priority is made to each of the above disclosed applications.

### TECHNICAL FIELD

The subject matter disclosed generally relates to pole pieces and uses thereof.

### PRIOR ART

Ernst, R. R., Bodenhausen, G., and Wokaun, A., Principles of Nuclear Magnetic Resonance in One and Two Dimensions, International Series of Monographs on Chemistry-14, Oxford University Press, 1990.
Halbach, K., “Design of Permanent Multipole Magnets with Oriented Rare Earth Cobalt Material,” Nuclear Instruments and Methods 169, 1-10, 1980.
Moresi, G. and Magin, R., “Miniature Permanent Magnet for Tabletop NMR,” Concepts in Magnetic Resonance Part B: Magnetic Resonance Engineering 19B (1), 35-43, 2003.
Rose, N. E., “Magnetic Field Correction in the Cyclotron,” Physical Review 53, 715-719, 1938.
Hamermesh, M., Group Theory and its Application to Physical Problems, Reading, MA, Addison-Wesley, 1962.
Innovating Approaches to the Generation of Intense Magnetic Fields: Design and Optimization of a 4 Tesla Permanent Magnetic Flux Source, Bloch. F, et al, IEEE Transactions on Magnetics 34, p2465, 1998.
U.S. patent application, Publication No. US2011/0137589 A1, and PCT Application, Publication No. WO 2011/066652, filed Dec. 1, 2010, both owned by the applicant and entitled “METHOD AND APPARATUS FOR PRODUCING HOMOGENEOUS MAGNETIC FIELDS”.
U.S. Pat. No. 3,611,223 to Utsumi, issued Oct. 5, 1971.
U.S. Pat. No. 4,093,912 to Double et al., issued Jun. 6, 1978.
U.S. Pat. No. 4,580,098 to Gluckstern, et al., issued Apr. 1, 1986.
U.S. Pat. No. 4,673,882 to Buford, issued Jun. 16, 1987.
U.S. Pat. No. 4,758,813 to Holsinger et al., issued Jul. 19, 1988.
U.S. Pat. No. 5,003,276 to Sarwinski et al., issued Mar. 26, 1991.
U.S. Pat. No. 6,275,128 to Aoki and Hashimoto, issued Aug. 4, 2001.
U.S. Pat. No. 6,566,991 to Rimkunas and Wahl, issued on May 20, 2003.
U.S. Pat. No. 6,768,407 to Kohda and Kumuda, issued on Jul. 27, 2004.
U.S. Pat. No. 7,199,689 to Abele, issued Apr. 3, 2007.
US Patent application publication 2002/0179830 A1 “HALBACH DIPOLE MAGNET SHIM SYSTEM”, published Dec. 5, 2002.
US Patent application publication 2009/0128272 A1 “HALBACH MAGNET ARRAY FOR NMR INVESTIGATIONS”, published May 21, 2009.
US Patent application publication 2010/0244828 A1 “ADJUSTABLE PERMANENT MAGNET ASSEMBLY FOR NMR AND MRI”, published Sep. 30, 2010
US Patent application publication 2011/0057655 A1 to Ando et al. “SOFTWARE FOR ADJUSTING MAGNETIC HOMOGENEITY, METHOD FOR ADJUSTING MAGNETIC HOMOGENEITY, MAGNET DEVICE, AND MAGNETIC RESONANCE IMAGING APPARATUS”, PUBLISHED Mar. 10, 2011.
Co-owned and co-invented International Patent Application No. PCT/CA2021/051793 entitled Pole Piece.

Where permissible by law, all references cited herein are hereby incorporated herein by reference in their entirety.

In many areas of technology, it is desirable to control the spatial distribution of magnetic fields carefully. Well-controlled magnetic fields are particularly important in nuclear magnetic resonance (NMR) spectroscopy and other magnetic resonance (MR) applications. In many NMR spectroscopy experiments, a strong, static magnetic field is applied in a region of space that contains a sample under study, and it is desirable that this field be as spatially uniform as possible in order to observe important but subtle variations in the magnetic response of the sample. It is also desirable in many NMR applications to have a static magnetic field that is as strong as is practical.

At least three classes of magnets have been used to provide a strong, static magnetic field in NMR devices: superconducting electromagnets, resistive electromagnets, and permanents magnets. Permanent magnets or arrays thereof can be advantageous in applications where low cost, low maintenance or portability are desirable. A particularly useful design for compact applications is a permanent magnet assembly based on Halbach cylinders, which comprise component magnets oriented and arranged around a central bore.

In practice, static magnetic field magnets, including permanent magnets, are often accompanied by pole pieces. The term “pole piece” is more fully defined herein but generally refers to a piece of magnetically permeable material placed in the vicinity of magnets in order to contribute to or shape a magnetic field. In some cases, additional devices or apparatus comprising magnetic materials are provided to shape the magnetic field for applications. Shaping the magnetic field oftentimes includes rendering it more spatially uniform, or “homogeneous”.

Prior art pole piece apparatuses sometimes comprise ancillary shimming elements. For example, a shim tray (magnetic field homogeneity adjuster) is disclosed in US patent application 2011/0057655A1 to Ando, et al. The shim tray is of a non-magnetic material, such as plastic or aluminum. The shim trays have a shape of a disk or the like and are provided with a number of threaded screw holes therethrough. Threaded shim bolts are provided, which are made of a magnetically permeable material. In magnetic field homogeneity adjustment, the shim bolts are screwed into the screw holes according to location data provided by a software program. The shim trays are disposed in a magnetic device designed so as to generate a homogeneous magnetic field using superconducting coils.

Disclosed in U.S. Pat. No. 6,275,128 to Aoki & Hashimoto is an MRI magnetic field generator with which the magnetic field uniformity within the imaging field of view of the air gap can be adjusted without having to detach the gradient coils, after the MRI magnetic field generator has been installed with gradient coils already mounted on a pair of magnetic pole pieces. Magnetic material pellets or permanent magnetic pellets for adjusting the magnetic field uniformity are inserted into the required pits disposed in a pattern to adjust the homogeneity of the field.

Such prior art configurations of shim elements are described in the context of large, open magnet devices with large pole structures, such as those used in magnetic resonance imaging (MRI) devices. Pole pieces found in imaging apparatuses for open magnet configurations often exhibit a circular overall shape with a flat front-face surface. There remains a need for improvements to pole pieces, pole piece production methods, and pole piece implementation methods, particularly when shimming a magnetic field produced by a much smaller arrangement of permanent magnets in the tight confines of a Halbach cylinder used in compact NMR applications.

### SUMMARY

The present embodiments address these needs.

According to one aspect of the invention, there is provided a pole piece assembly for use in a Halbach-type magnet configuration, the pole piece assembly comprising a rear face, a front face S, and ends separated by a first distance defining a length of said pole piece assembly along a first axis extending between said ends, said pole piece assembly being configured for insertion into an interior of the Halbach-type magnet configuration along said first axis, wherein a surface of the front face S is curved, and wherein a curvature of the front face is mathematically defined for shimming the magnetic field generated by the magnet configuration.

In an embodiment, the pole piece assembly is elongated in shape along the first axis.

In an embodiment, the pole piece assembly further comprises: a reference plane, P, containing an origin point, O, the reference plane being in a three-dimensional volume occupied by and surrounding the pole piece assembly; a cartesian reference frame, fixed at O, comprising length, width, and height axes (\hat{x}, ŷ, and \hat{z}), and corresponding Cartesian coordinates x, y, and z respectively along said axes; and a rectangular region, R, having length, l, and width, w, lying in reference plane P and centered at origin point O, the rectangular region having sides parallel to the x and y axes of the cartesian reference frame and containing points having cartesian coordinates (x, y) satisfying −½l≤x≤+½l and −½w≤y≤+½w; wherein points lying on the front face surface S are described by a smooth depth-function z(x, y) of the cartesian coordinates, defined on R, the depth-function quantifying the perpendicular distance, z, from R to the corresponding point on S; and wherein the depth-function takes the form z(x, y)=Σ_{i,j}^{□}cᵢⱼfᵢ(x)gⱼ(y), where functions fᵢ and gⱼ are smooth basis functions selected from basis-function sets Ωₓ and Ω_{y}, and where cᵢⱼ are expansion coefficients.

In an embodiment, the reference plane, P, is coincident with a physical, flat surface on a body of the pole piece assembly.

In another embodiment, the reference plane, P, is an abstract plane in the three-dimensional volume occupied by and surrounding the pole piece assembly.

In an embodiment, a main body of said pole piece assembly is made of a magnetically permeable material.

In an embodiment, a main body of said pole piece assembly acquires a magnetic polarization when placed in a magnetic field.

In an embodiment, said basis-function sets Ωₓ and Ω_{y} are sets of orthogonal polynomials, Jacobi polynomials, Legendre polynomials, Laguerre polynomials, Chebyshev polynomials, hypergeometric functions, trigonometric functions, inverse trigonometric functions, hyperbolic functions, inverse hyperbolic functions, Bessel functions, Gaussian functions, rational functions, Pade approximants, or associated Legendre functions or are scaled sums, products, quotients, or compositions thereof.

The pole piece may further comprise a shimming hole adapted to accept the insertion thereinto of at least one cooperating shimming rod.

In an embodiment, the shimming hole comprises a female screw thread and said shimming rod comprises a cooperating male screw thread so that the shimming rod can be screwed into the pole piece assembly.

The pole piece assembly may also comprise: a main pole piece body having a front face and a rear face; a shim insert body having a front face and a rear face, the shim insert body being adapted to receive and/or be received by the main pole piece body to form the pole piece assembly such that the rear face of the main pole piece body faces the front face of the shim insert body when in an assembled position; a depression formed in at least one of: the rear face of the main pole piece body and the front face of the shim insert body, such that an interstitial shim cavity is formed by the depression when the main pole piece body and the shim insert body are in an assembled position; and an interstitial shim layer provided in the interstitial shim cavity.

In an embodiment, the shim insert body defines shim insert holes adapted to accept the insertion thereinto of one or more shim inserts.

In another embodiment, said one or more shim inserts are threaded and engage a cooperating reciprocal thread on the inside surface of the receiving shim insert holes so that the shim inserts can be screwed into the pole piece assembly.

In yet a further embodiment, a depth of the depression is greater than a thickness of the interstitial shim layer to allow for insertion of a material having the same or different magnetic properties above or underneath the interstitial shim layer for shimming the magnetic field generated by the Halbach-type magnet configuration.

In another aspect, there is provided a magnetic resonance device comprising a pole piece assembly for use in a Halbach-type magnet configuration, the pole piece assembly comprising a rear face, a front face S, and ends separated by a first distance defining a length of said pole piece assembly along a first axis extending between said ends, said pole piece assembly being configured for insertion into an interior of the Halbach-type magnet configuration along said first axis, wherein a surface of the front face S is curved, and wherein a curvature of the front face is mathematically defined for shimming the magnetic field generated by the magnet configuration.

In a further aspect, there is provided a method for shimming a magnetic field generated by a Halbach-type magnet configuration, the magnet configuration at least partly enclosing a sample volume, the method comprising:
identifying a magnetic field inhomogeneity in the sample volume of the Halbach-type magnet configuration, the inhomogeneity being generated by a magnetic field gradient;
providing a pole piece assembly, the pole piece assembly comprising a main pole piece body, the main pole piece body comprising:
a curved front face surface S;
a reference plane, P, containing an origin point, O;
a cartesian reference frame, fixed at O, comprising length, width, and height axes, \hat{x}, ŷ, and \hat{z}, respectively, and corresponding cartesian coordinates x, y, and z;
a rectangular region, R, having length, l, and width, w, lying in reference plane P and centered at origin point O, the rectangular region having sides parallel to the x and y axes of the cartesian reference frame and containing points having cartesian coordinates (x, y) satisfying −½l≤x≤+½l and =½w≤y≤+½w,
wherein points lying on the front face surface S are described by a smooth depth-function z(x, y) of the cartesian coordinates, defined on R, the depth-function quantifying the perpendicular distance, z, from R to the corresponding point on S; and
wherein the depth-function takes the form

$$z ( x , y ) = {\sum }_{i , j}^{□} {c}_{i j} {f}_{i} ( x ) {g}_{j} ( y ) ,$$

where functions fᵢ and gⱼ are smooth basis functions selected from basis-function sets Ωₓ and Ω_{y}, and where cᵢⱼ are expansion coefficients;
forming a modified main pole piece body by performing one or more of: removing material from, or adding material to the main pole piece body based on the identified magnetic field inhomogeneity; and
inserting a modified pole piece assembly comprising the modified main pole piece body into the Halbach-type magnet configuration to shim the magnetic field.

In an embodiment, the method may further comprise identifying one or more additional magnetic field inhomogeneities generated by one or more additional magnetic field gradients; and repeating the steps of identifying to inserting for each of the one or more additional magnetic field inhomogeneities.

In another embodiment, the method may further comprise identifying the magnetic field inhomogeneity by simulating a magnetic field generated by modifying the front face surface of the main pole piece body by adjusting the coefficients cᵢⱼ in the depth-function defining the front face surface S.

In an embodiment, the method may further comprise identifying the magnetic field inhomogeneity by measuring a magnetic field generated by modifying the front face surface of the main pole piece body according to adjustments of the coefficients cᵢⱼ in the depth-function defining the front face surface S and using a magnetic field mapping device to record changes in field configuration corresponding to said adjustments.

In an embodiment, said basis-function sets Ωₓ and Ω_{y} are sets of orthogonal polynomials, Jacobi polynomials, Legendre polynomials, Laguerre polynomials, Chebyshev polynomials, hypergeometric functions, trigonometric functions, inverse trigonometric functions, hyperbolic functions, inverse hyperbolic functions, Bessel functions, Gaussian functions, rational functions, Pade approximants, or associated Legendre functions or are scaled sums, products, quotients, or compositions thereof.

In an embodiment, the method may further comprise assembling two modified pole piece assemblies and a positioner into a central cavity assembly prior to inserting the two modified pole piece assemblies into the Halbach-type magnet configuration.

Features and advantages of the subject matter hereof will become more apparent in light of the following detailed description of selected embodiments, as illustrated in the accompanying figures. As will be realized, the subject matter disclosed and claimed is capable of modifications in various respects, all without departing from the scope of the claims. Accordingly, the drawings and the description are to be regarded as illustrative in nature, and not as restrictive and the full scope of the subject matter is set forth in the claims.

### BRIEF DESCRIPTION OF THE DRAWINGS

Further features and advantages of the present disclosure will become apparent from the following detailed description, taken in combination with the appended drawings, in which:

FIG. 1A is a perspective front view of an assembled pole piece assembly in accordance with an embodiment;

FIG. 1B is a perspective rear view of an assembled pole piece assembly in accordance with the embodiment of FIG. 1A;

FIG. 2 is a perspective front view of an assembled pole piece assembly in accordance with the embodiment of FIG. 1A, showing a reference plane, coordinate axes, and a rectangular region in the reference plane;

FIG. 3A is an exploded front view of a pole piece assembly, in accordance with the embodiment of FIG. 1A;

FIG. 3B is an exploded rear view of a pole piece assembly, in accordance with the embodiment of FIG. 1A;

FIG. 4A is a front view of an assembled pole piece assembly in accordance with the embodiment of FIG. 1A;

FIG. 4B is a rear view of an assembled pole piece assembly in accordance with the embodiment of FIG. 1A;

FIG. 4C is a side view of an assembled pole piece assembly in accordance with the embodiment of FIG. 1A;

FIG. 4D is an end view of an assembled pole piece assembly in accordance with the embodiment of FIG. 1A,

FIG. 5A is an exploded perspective view of a central cavity assembly comprising first and second pole piece assemblies in accordance with the embodiment of FIG. 1A;

FIG. 5B is a perspective view of the central cavity assembly comprising first and second pole piece assemblies in accordance with the embodiment of FIG. 5A;

FIG. 5C is a perspective view of the central cavity assembly of FIG. 5B, the central cavity assembly comprising shimming rods;

FIG. 6 is a block diagram of a magnetic resonance device including pole piece assemblies, in accordance with an embodiment of the disclosure;

FIG. 7A is a schematic cross-sectional view of a magnet array (assembly) including two pole piece assemblies in accordance with an embodiment; and

FIG. 7B is a schematic cross-sectional view of a magnet array (assembly) including two pole piece assemblies in accordance with a further embodiment.

It will be noted that throughout the appended drawings, like features are identified by like reference numerals.

### DETAILED DESCRIPTION

Described is a pole piece assembly comprising a main pole piece body having a curved front face surface. The main pole piece body is made of a magnetically permeable material. Accordingly, the main pole piece body acquires a magnetic polarization when placed in a magnetic field. The main pole piece body comprises:
A curved front face surface, S;
A reference plane, P, containing an origin point, O;
A Cartesian reference frame, fixed at O, comprising length, width, and height axes, \hat{x}, ŷ, and \hat{z}, respectively, and corresponding Cartesian coordinates x, y, and z;
A rectangular region, R, having length, l, and width, w, lying in reference plane P and centered at origin point O, the rectangular region having sides parallel to the x and y axes of the Cartesian reference frame and containing points having Cartesian coordinates (x, y) satisfying −½l≤x≤+½l and −½w≤y≤+½w,
wherein points lying on the front face surface S are described by a smooth depth-function z(x, y) of the Cartesian coordinates, defined on R, the depth-function quantifying the perpendicular distance, z, from R to the corresponding point on S,
and wherein the depth-function takes the form

$$z ( x , y ) = {\sum }_{i , j}^{□} {c}_{i j} {f}_{i} ( x ) {g}_{j} ( y ) ,$$

where functions fᵢ and gⱼ are smooth basis functions selected from basis-function sets Ωₓ and Ω_{y}, and where cᵢⱼ are expansion coefficients.

The reference plane, P, is not necessarily coincident with a physical, flat surface on the main pole piece body. Rather, it is an abstract plane in the three-dimensional volume occupied by and surrounding the pole piece assembly, which is used to define the surface S mathematically.

In an embodiment, the pole piece assembly is adapted or configured for use in a Halbach-type magnet configuration, the pole piece having an elongated body adapted for insertion into the Halbach-type magnet configuration. In an embodiment, the pole piece assembly comprises a main pole piece body formed of a single piece of material. In a further embodiment, the pole piece assembly may comprise at least two parts operably and removably connected to each other. The at least two parts of the pole piece may comprise a main pole piece body having a front face and a rear face, a shim insert body having a front face and a rear face, and an interstitial shim layer adapted to be inserted in a shim cavity defined by a depression formed in at least one of: the rear face of the main pole piece body and the front face of the shim insert body. The shim insert body may also be adapted to be inserted in a shim cavity positioned in the rear face of the main pole piece body. A method for shimming is also disclosed which includes modifying a material content of the shim cavity and inserting the pole piece assembly into the central cavity of the Halbach-type magnet configuration for shimming the magnetic field generated.

In the present disclosure the term “pole piece” refers to at least one piece of magnetically permeable material placed in the vicinity of primary magnets for use in contributing to or shaping the primary magnetic field or intended to be placed in the vicinity of primary magnets for use in contributing to or shaping the primary magnetic field. In embodiments pole pieces and assemblies comprising pole pieces are suitable for use in confined spaces, and for example but not by way of limitation, in embodiments pole pieces and assemblies comprising pole pieces are suitable for use in the central space or cavity of a magnet array which in embodiments is a Halbach array and in embodiments is in a magnetic resonance device. In other embodiments, the magnet array comprises a first plurality of magnets arranged in a Halbach cylinder configuration and a second plurality of magnets arranged in a non-Halbach cylinder configuration. In further embodiments, such pluralities of magnets may be accompanied by parts made of soft magnetic materials, and such parts are distinct from the main pole piece body or pole piece assembly Such parts may be located outside the main magnet assembly, inside a bore of the magnet assembly, or inside an expanded bore and may serve one or more functions to shape, strengthen, shield, or confine the local magnetic field.

The present disclosure contemplates use of pole pieces within confined spaces in magnetic field-producing devices. In the present disclosure the term “Halbach-type” magnet array (magnet configuration, magnet assembly) refers to magnet arrays comprising component magnets arranged in a Halbach configuration. In all places in the present disclosure where the term Halbach-type magnet array (or assembly) is used, such Halbach-type magnet arrays may also include other magnetic components in addition to those in the Halbach configuration, and the inventive disclosure is contemplated to include all such modifications.

In particular embodiments pole pieces consist of or comprise any suitable material or substance, including but not limited to iron, cobalt, nickel, other chemical elements, and alloys thereof and may be of any suitable shape and size.

In particular embodiments, a pole piece assembly for use in a Halbach-type magnet configuration comprises a rear face, a front face, and ends separated by a first distance defining a length of the pole piece assembly along a first axis extending between the ends of the pole piece assembly. The pole piece assembly is configured for insertion into an interior of the Halbach-type magnet configuration along the first axis. A surface of the front face of the pole piece assembly is curved and a curvature of the front face is mathematically defined for shimming the magnetic field generated by the magnet configuration.

In particular embodiments, pole pieces or pole piece assemblies are substantially elongated in one dimension and have a front face or a rear face or a front face and a rear face, or a front face, a rear face, ends and a length. Pole pieces or pole piece assemblies may be elongated in shape along a length or first axis of the pole piece assembly. It will be understood that in use, the front face of a pole piece is or comprises a surface of the pole piece that is oriented towards or is proximate to a defined volume or sample volume or sample, and distal to an associated magnet or magnet assembly whose field the pole piece is intended to influence. Conversely, the rear face of a pole piece refers to a surface or portion of the surface of the pole piece that is proximate to one or more magnets whose field the pole piece is intended to influence and distal to a defined volume or sample volume wherein a sample is to be positioned.

In exemplary, but non-limiting, embodiments, pole pieces or pole piece assemblies may be substantially elongated, meaning that the length may be 10% longer than the width of the pole piece. In other embodiments, the length may be 50% longer than the width or anywhere between 10% and 50%. In other embodiments, the length may be anywhere between 50% longer than the width and 100% longer than the width. In other embodiments, the length may be anywhere between 100% longer than the width and 200% longer than the width. In other embodiments, the length may be significantly longer, for example, 200% longer or more than the width of the pole piece or pole piece assembly.

In the present disclosure, the term “main pole piece body” refers to the segment or part or portion of a pole piece or pole piece assembly whose front face is proximate to a designated sample volume. In aspects of the inventive disclosure, the front face surface is generally curved, and in embodiments the surface curvature may be described according to a mathematical formula.

In the present disclosure the term “pole piece assembly” refers to a pole piece that comprises a main pole piece body and ancillary structures, magnetic or non-magnetic or partially magnetic, to which the main pole piece body is directly attached/connected. Such structures may include shim inserts (or shim insert bodies), shim insert screws, shimming screws, mounting screws, interstitial shim layers, or the like.

In the present disclosure a “magnet array” into which a pole piece or pole piece assembly is inserted means an arrangement of magnets configured to generate a desired magnetic field and may include a Halbach cylinder, Halbach sphere, other Halbach array or an array comprising magnets arranged in Halbach and non-Halbach configurations. In embodiments pole pieces are comprised in or are used in association with any form of magnet array, including but not limited to arrays wherein one or more primary magnets may be placed outside each pole piece, and wherein a permeable magnetic material may be placed further outside the primary magnets so as to confine or shield the magnetic flux.

In the present disclosure the term “shimming” refers to any method for suppressing magnetic field inhomogeneity, including but not limited to inhomogeneity in a primary field generated by a magnet array. For greater certainty it will be understood that the term shimming includes both active shimming, wherein the shimming effect may be achieved by the application of a current to thereby generate an induced and user-determined magnetic shimming field, and passive shimming wherein the shimming effect is achieved solely by the positioning of a ferromagnetic or other object having predetermined magnetic properties.

In the present disclosure “suppressing” an inhomogeneity refers to any adjustment to the geometrical or functional components of a magnetic field to correct or smooth out or otherwise adjust, overcome or modify undesired irregularities or distortions in the field. Suppressing according to embodiments comprises complete or partial suppressing and in embodiments affects one or more geometrical or functional components of the field. In particular embodiments suppressing is actuated to cause a magnetic field to adopt a predetermined desired degree of homogeneity.

It is convenient when characterizing a magnetic field to consider the spatial dependence of the field, that is, to represent the field, \vec{B}(x, y,z) as a function of spatial coordinates, such as Cartesian coordinates (x, y, z) defined with respect to an origin point. Said function of coordinates may itself further be described, or estimated for the purposes of analysis, as a sum or expansion on a set of basis functions:

$$\vec{B} ( x , y , z ) = {B}_{0} \hat{z} + {\sum }_{i} {a}_{i} {\vec{g}}_{i} ( x , y , z ) ,$$

Where \hat{z} denotes a unit vector along the z-coordinate axis, where \vec{g}ᵢ (x, y, z) denotes said basis functions, and where B₀ and aⱼ denote coefficients.

In the present disclosure, a “functional component” of a magnetic field means the strength of the part of the field characterized by a given \vec{g}ᵢ(x, y, z) basis function in this type of expansion as quantified by its corresponding coefficient, aᵢ. Moreover, suppressing the inhomogeneity corresponding to such a functional component means reducing the numerical value of the corresponding coefficient. In the present disclosure, sometimes these individual functional components are called “gradients” or “magnetic field gradients”.

In embodiments of the present disclosure, the magnetic field is a primary magnetic field and is generated or maintained within a magnetic resonance device, which in embodiments is a nuclear magnetic resonance (NMR) machine, and in embodiments is a spectrometer (instrument) and in embodiments is a compact NMR machine.

In the present disclosure the term “magnetic resonance” or “MR” means resonant reorientation of magnetic moments of a sample in a magnetic field or fields, and includes nuclear magnetic resonance (NMR), electron spin resonance (ESR), magnetic resonance imaging (MRI) and ferromagnetic resonance (FMR). As the present disclosure pertains to methods and apparatuses for rendering general static magnetic fields more uniform, in embodiments the disclosure is also applicable in ion cyclotron resonance (ICR) or in trapped-ion or particle-beam technology generally. For simplicity of explanation, the term magnetic resonance or MR as used herein will be understood to include all these alternative applications. In particular applications and embodiments, the apparatuses and methods disclosed are applied to NMR, and in embodiments they are applied to NMR spectrometers or to NMR imagers. Materials that display magnetic resonance when exposed to a magnetic field are referred to as magnetically resonant or MR active nuclides or materials.

In the present disclosure the term “sample” has its broadest possible meaning consistent with the disclosure hereof and means any item or material that may be, or may be desired to be, examined or tested using magnetic fields or within which it may be desired to induce or measure or detect magnetic resonance, or which it may be desired to examine using embodiments of the subject matter disclosed herein. In particular embodiments, samples include or comprise or consist of solid and non-solid objects and materials, living, non-living or deceased materials, chemicals, structures, devices, gases, liquids, and solids, or any combinations of any of the foregoing, such as solutions, colloids, slurries, gels, foams, pastes, or the like. In particular embodiments and without limitation a sample includes one or more organisms or tissues, and such organisms or tissues are or include plants, animals, and microorganisms, and include human and animal subjects or parts thereof. Without limitation the term sample includes experimental or medical subjects of any kind whatsoever, whether living, deceased or non-living.

In the present disclosure, the term “sample volume” refers to a volume of space wherein a sample may be placed and exposed to a main or primary magnetic field for the purposes of detecting the magnetic resonance properties of the sample, including determining the presence, absence, or characteristics of magnetic resonance in the sample. The sample volume is of any suitable dimensions and in embodiments is enclosed or partly enclosed and is or is capable of being a vacuum or partial vacuum or being atmosphere-controlled or temperature controlled. In embodiments the sample volume is a region within the central space or cavity of a magnet array. In embodiments the sample volume has disposed thereabout pole piece assemblies, shim paths, shim panels and such other apparatus as may be necessary or desirable for applying magnetic resonance to the sample and analyzing the sample. In particular embodiments the sample volume is or is within or comprises a hexagonal or cylindrical or other shaped cavity and in embodiments is bounded by one or more of a plurality of magnets, pole piece faces, glass tubes, or other physical means of confinement, or is defined by an abstract geometrical surface relative to a point in space. In embodiments the sample volume comprises or defines space for apparatus(es) suitable to spin, rotate or otherwise move or position the sample.

In the present disclosure the term “channel,” where used with reference to a pole piece body, means any form of channel, groove, recess, or concavity in a surface of the pole piece and any adjustment to a volume or portion of the pole piece that reduces or changes the magnetic permeability in that volume or portion of the pole piece.

In embodiments a channel is filled with any desired material which has desired magnetic or non-magnetic properties, or is chosen to strengthen, lighten, intensify, diminish, or otherwise modify or adjust the physical and magnetic properties of the pole piece in a manner desired by a user.

In embodiments a channel extends for all or substantially all of the length of a pole piece and in embodiments a channel extends for a fraction of the length of the pole piece, which fraction may be substantially less than the length of said pole piece and may be more or less than about 10%, 20%, 30%, 40%, 50%, 60%, 70%, 80%, or 90% of the length of the pole piece. In embodiments, a material used to fill a shaped channel in a main pole piece body, interstitial shim layer, or front iron may comprise holes, depressions, or other shaped features, and said holes may be threaded and left open or provided with screw-shaped inserts that are threaded correspondingly to permit movement of the inserts.

Where multiple channels are provided in embodiments a plurality of channels are of substantially the same dimensions and in alternative embodiments channels have different dimensions. In embodiments one or more of the inner surfaces of a channel are optionally textured in all manner of ways and in embodiments are partly or wholly substantially smooth, ridged, corrugated, grooved, dimpled, and/or scratched and in embodiments bear protrusions or recesses or both protrusions and recesses and in embodiments any grooves, ridges, corrugations, dimples, scratches and other surface features are oriented in any desired directions. It will be understood that ridges, whether present in a channel or on the front face or other surface of a pole piece, may have a range of geometries and in particular embodiments ridges are of uniform cross-section, uniform height, uniform separation, uniform length and uniform orientation. In alternative embodiments ridges are of non-uniform cross-section, non-uniform height, non-uniform separation, non-uniform length and non-uniform orientation and in embodiments are notched.

In alternative embodiments a channel is produced in a pole piece by cutting, preforming, compression or any other suitable means. Where a plurality of channels is provided these may be sized, shaped and filled in identical manners, or in different manners as required by a user.

In embodiments a pole piece comprises one channel and in alternative embodiments comprises two, three, four, five, six, seven, eight, nine, ten, eleven, twelve or more channels. Where multiple channels are provided, in embodiments they extend for a part or all of the length of the pole piece, or are symmetrically arranged, or are asymmetrically arranged, or are longitudinally oriented or are transversely oriented or are the same or different lengths, depths, widths or otherwise have the same or different geometries or properties. In embodiments comprising more than one channel, such channels may be of equal or different lengths and may be equally or differently spaced from one another. In alternative embodiments channels may be straight or curved and may be continuous or discontinuous along the length or width or the channels.

In the present document the term “shimming rod” or “shimming insert” means a body used to adjust the magnetic field proximate to a pole piece and the term “shimming hole” means a hole in a pole piece or shim insert body adapted (including shaped and sized) to accept the insertion of a cooperating shimming rod thereinto. In embodiments, shimming rods are made of a magnetically permeable material whose magnetic permeability is similar to or the same as that of the pole piece itself or in alternative embodiments the magnetic permeability of the shimming rod is different from that of the pole piece. Shimming rods or shimming inserts and shimming holes according to particular embodiments are cylindrical, or polygonal in shape and boundary, or have any other cross section. Shimming rods and shimming holes are optionally shaped in a variety of manners to allow the desired amount of freedom for the position of the shimming rod to be adjusted relative to the pole piece. In particular embodiments and without limitation, shimming rods and shimming holes have cross sections that are substantially regular or irregular and/or that are substantially circular, oval, triangular, rectangular, square, rhomboidal, pentagonal, hexagonal, heptagonal, octagonal, nonagonal, decagonal or that have 3, 4, 5, 6, 7, 8, 9, 10 or more sides. It will be understood that a shimming hole need not be enclosed on all sides, so that in some embodiments a shimming hole is open along one side.

It will be further understood that in embodiments a shimming rod or rods are positioned relative to a pole piece, but are not inserted thereinto, or are only inserted partially into the shimming hole or partially into a channel in a face or portion of the pole piece.

It will also be understood that where a shimming rod or shim insert is to be rotated or is to be threadingly engaged with a cooperating shimming hole or shim insert hole, by means of reciprocal threads, then the geometry of the rod or insert and shimming hole or shim insert hole will be adjusted to facilitate this use. It will be understood that the descriptor “threadingly” may alternatively be used to describe such reciprocal threading engagement. The shimming hole or shim insert hole may comprise a female screw thread and the shimming rod or shim insert may comprise a cooperating male screw thread so that the shimming rod or shim insert can be screwed into the pole piece or pole piece assembly. It will be understood that herein where reference is made to a shimming rod that is associated with a pole piece, it is meant that such shimming rod is proximate to such pole piece, and in embodiments is inserted into such pole piece, and in other embodiments is merely positioned outside of but at a distance from such pole piece.

In embodiments, shimming rods or shimming inserts are threaded and engage a cooperating reciprocal thread on the inside surface of the receiving shimming hole. In embodiments such threading engagement serves to position the rod or insert and to secure the rod or insert into the hole and the geometry of the rod or insert and the rod-receiving or insert-receiving hole will be chosen to permit the necessary rotation.

One way to produce magnetic fields in a specified volume, in magnetic resonance as in other areas of technology, is to place permanent magnets near or around the volume. A relatively efficient design for producing a substantially strong field in a small volume is the Halbach cylinder or sphere, wherein permanent magnet materials are oriented in a well-defined way and arranged around a central cavity. To increase the strength of a magnetic field in a magnet array, the present embodiments describe the use of a specific type of pole piece assemblies. Pole pieces can acquire a magnetic polarization when placed in a magnetic field. This polarization can increase the strength of the magnetic field in the region of space near the pole piece to a value that is larger than it would be in the absence of the pole piece. Sometimes in applications it is desirable to use pole pieces or pole piece assemblies in pairs rather than individually.

The present disclosure will be more readily understood by referring to the following examples which are given to illustrate the invention rather than to limit its scope.

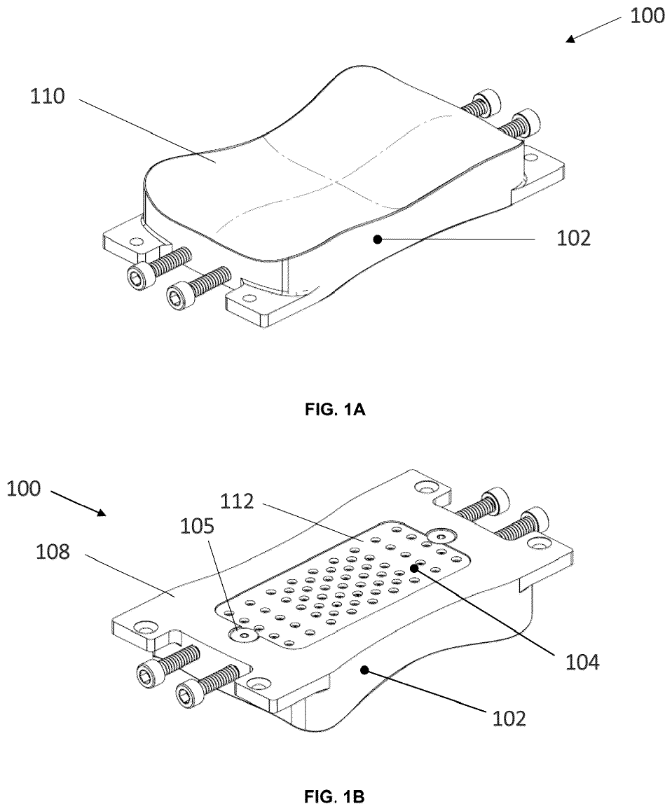

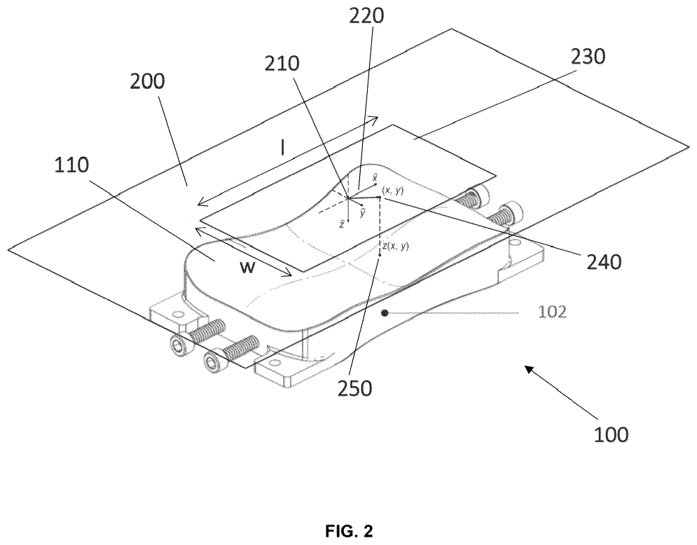

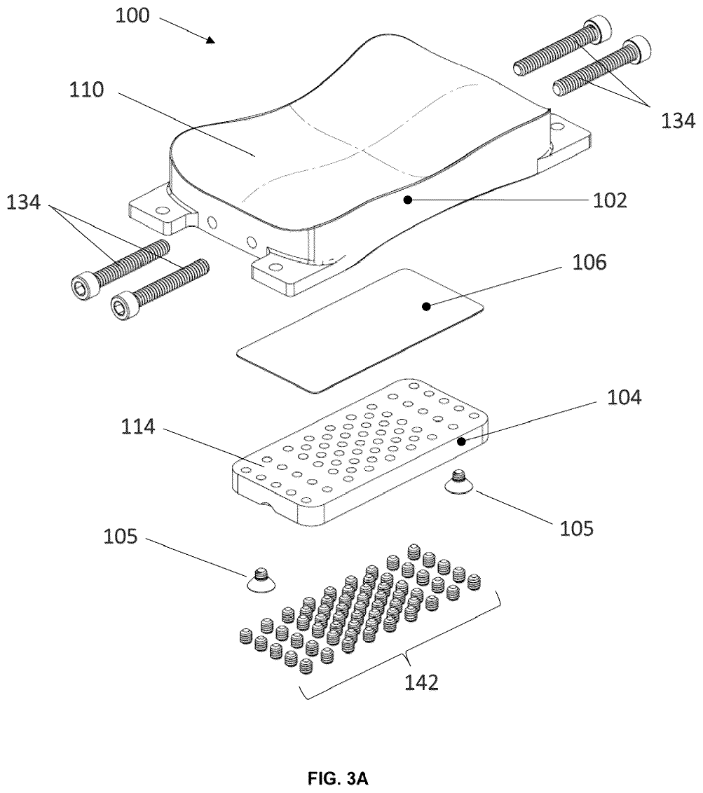

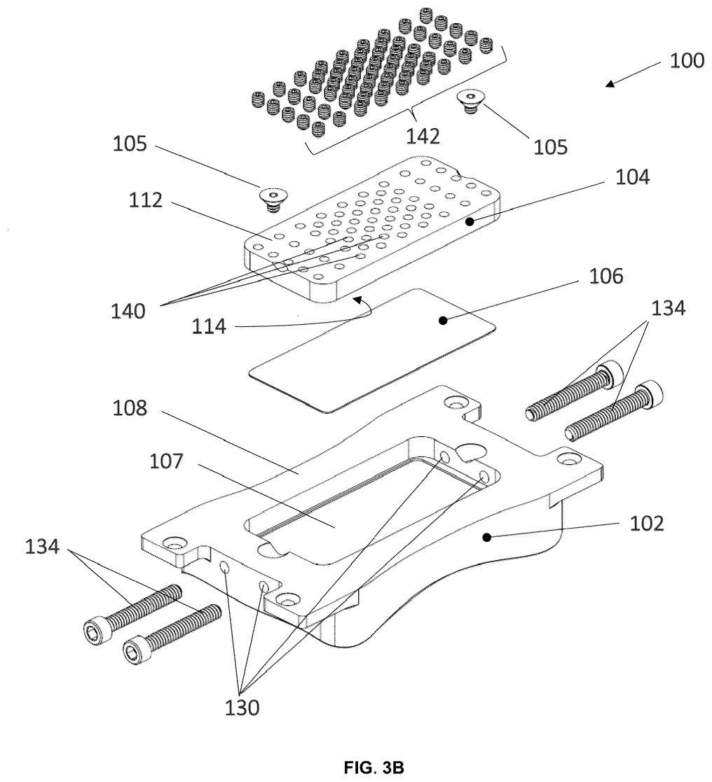

FIG. 1A and FIG. 1B are front and rear perspective views, respectively, of a pole piece assembly 100 in accordance with an embodiment. FIG. 2 is a front perspective view of an assembled pole piece assembly 100, in accordance with the embodiment of FIGS. 1A and 1B, showing a reference plane 200 and Cartesian coordinate system 220. FIG. 3A and FIG. 3B are front and rear exploded views, respectively, of a pole piece assembly 100, in accordance with the embodiment of FIGS. 1A and 1B.

In FIG. 1A there is illustrated a pole piece assembly 100 comprising a main pole piece body 102, and the main pole piece body 102 exhibits a substantially curved front face surface 110. The main pole piece body 102 is made of a magnetically permeable material (such as iron, cobalt, nickel, other chemical elements, or alloys thereof). Accordingly, the main pole piece body acquires a magnetic polarization when placed in a magnetic field in applications. With reference to FIG. 2, the front face surface 110 may be described mathematically.

In FIG. 2, the pole piece assembly 100 is shown with a reference plane 200, containing an origin point 210. A Cartesian reference frame 220, fixed at origin point 210, is also shown. Cartesian reference frame 220 comprises length, width, and height axes, \hat{x}, ŷ, and \hat{z}, respectively, and corresponding Cartesian coordinates x, y, and z. A rectangular region 230, lying in reference plane 200, is also exhibited centered at origin point 210 and with sides parallel to the x and y axes of Cartesian reference frame 220. Rectangular region 230 has a length/along the x axis and a width w along the y axis and accordingly contains points having Cartesian coordinates (x, y) satisfying −½l≤x≤+½l and −½w≤y≤½w within the rectangular region 230.

One may define a real-valued function z(x, y) on points (x, y) in the rectangular region 230. In an aspect of the disclosure, a subset of points lying on the front face surface 110 of the main pole piece body 102 are described by a smooth depth-function z(x, y) of the Cartesian coordinates (x, y) of points lying in rectangular region 230, the depth-function quantifying the perpendicular distance, z(x, y), from a point 240 lying on plane 200 having Cartesian coordinates (x, y, 0) to a corresponding point 250 lying on front face surface 110 having Cartesian coordinates (x, y, z(x, y)).

In a further aspect of the inventive disclosure, the depth-function takes the form z(x, y)=Σ_{i,j}^{□}cᵢⱼfᵢ(x)gⱼ(y), where functions fᵢ and gⱼ are smooth basis functions selected from basis-function sets Ωₓ and Ω_{y}, and where cᵢⱼ are expansion coefficients.

The reference plane 200 is not necessarily coincident with a physical, flat surface on the main pole piece body. Rather, it is an abstract plane in the three-dimensional volume occupied by and surrounding the pole piece assembly, which plane is used to mathematically define the front face surface 110. For clarity, in embodiments, the function z(x, y), in combination with the rectangular region 230, may describe the whole of the front face surface 110 and in other embodiments may describe only a portion of the front face surface.

With reference to FIG. 3A and FIG. 3B, there is illustrated a pole piece assembly 100 comprising a main pole piece body 102, a shim insert body 104 and an interstitial shim layer 106 provided between the main pole piece body 102 and the shim insert body 104.

The main pole piece body 102 comprises a rear face 108 as shown in FIG. 3B and a front face 110 as shown in FIG. 3A. The shim insert body 104 has a rear face 112 as shown in FIG. 3B and a front face 114 as shown in FIG. 3A. Once assembled, the pole piece assembly 100, as shown in FIG. 1A and FIG. 1B, has a rear surface composed of the rear face 108 of the main pole piece body 102 and the rear face 112 of the shim insert body 104. A channel (not shown) may in embodiments be provided in the rear face of the pole piece 100. As shown in FIGS. 1B and 3B, the rear face 112 of the shim insert body may in embodiments comprise a pattern of apertures (shim insert holes) 140 that have been formed in the surface.

In embodiments, the rear face 108 of the main pole piece body 102 and the rear face 112 of the shim insert body 104 lie in the same plane, and in alternative embodiments they do not lie in the same plane and are at different heights when the pole piece assembly is assembled. In further alternative embodiments, each said surface may be substantially flat and in other alternative embodiments either surface may exhibit a curvature.

In the embodiment of FIG. 3B, the rear face 108 of the main pole piece body 102 comprises a depression (hollow space or cavity) 107 which is adapted to receive the interstitial shim layer 106 when the main pole piece body 102 and the shim insert body 104 are assembled as in FIG. 1B. In embodiments, shim insert mounting screws 105 may be provided to secure the shim insert body 104 into the main pole piece body 102.

In another embodiment (not shown), a depression may be provided in the front face 114 of the shim insert body 104, either to replace the depression 107 or to be an extension thereof. In other words, the depression of the front face 114 can be provided instead of the depression 107 or in addition to the depression 107, in which case, the two depressions can face each other and preferably overlap each other (at least partially) to define a single hollow space into which the interstitial shim 106 can be positioned. In this disclosure, this hollow space is called the interstitial shim cavity.

The depression 107 is shaped and dimensioned to receive the interstitial shim layer 106 therein when the main pole piece body is assembled with the shim insert body to form an interstitial shim cavity between the two. In one embodiment, the depression (and likewise the interstitial shim cavity) may have a depth that exceeds the thickness of the interstitial shim layer 106 whereby (not shown) additional material having the same or different magnetic properties may be added on top (or underneath) the interstitial shim layer 106 in order to shim a magnetic field and/or suppress the field's inhomogeneity in order to reach the desired characteristics of a magnet assembly and/or magnetic resonance device into which the pole piece assemblies are assembled, inserted or implemented.

Additional material added on top or underneath the interstitial shim layer 106 may in embodiments take the form of flat sheets of one or more shapes, and of the same or a different material than the interstitial shim layer, main pole piece body or shim insert body. The additional material may be either solid or patterned with holes, slits, pits, channels, or other raised or lowered regions of the additional material. The additional material may be made of ferromagnetic material or non-ferromagnetic material or a combination of ferromagnetic and non-ferromagnetic materials. In embodiments, a portion of the additional material may be made of a magnetically soft, ferromagnetic material and may comprise flat buttons or plates of various sizes, shapes, and thicknesses positioned on top or underneath the interstitial shim layer 106 by a user or machine.

The interstitial shim layer 106 comprises a substantially flat piece of magnetically permeable, ferromagnetic metal. The interstitial shim layer 106 comprises a rear face (oriented towards the shim insert body 104) and a front face (oriented towards the main pole piece body 102). In operation, the interstitial shim layer may have material removed therefrom through a variety of subtractive processes not limited to chemical etching, machining, scratching, die-punching, laser cutting, water-jet cutting, grinding and/or gouging. This removal of material is undertaken to shim the magnetic field and/or suppress the field's inhomogeneity in order to reach the desired characteristics of a magnet assembly and/or magnetic resonance device into which the pole pieces are assembled, inserted or implemented. This removal of material may occur in a manner that defines one or more apertures through the entire thickness of the interstitial shim layer. Alternatively, removal of material may take place at either the front face (surface visible in FIG. 3A) of the interstitial shim layer or the rear face (surface visible in FIG. 3B), or on both surfaces, with variable depths of material removed being under the control of the user, machine, or process for material removal.

In one example, the interstitial shim layer may have a thickness of about 0.1 mm (about 0.004 inch). The interstitial shim cavity formed from the depression (107 in FIG. 1A) in the main body 102 or created by both the main body 102 and the second body 104 when assembled, or both, which receives the interstitial shim layer in this example may have a corresponding depth of about 0.1 mm (about 0.004 inch) or more than about 0.1 mm (about 0.004 inch) to receive the interstitial shim layer. Alternatively, a depression in each of the main body or the second body may each have a depth of about 0.1 mm to receive two interstitial shim layers stacked atop one another. Various other alternatives are possible, including a thicker or thinner interstitial shim layer, more than one interstitial shim layer stacked atop one another, and depressions of different depths for receiving the one or more interstitial shim layers in the main body, the second body, or both the main body and the second body.

In another example, the interstitial shim layer may have a thickness of about 0.1 mm (about 0.004 inch), and the interstitial shim cavity formed from a depression in either the main body or the second body, or both, which receives the interstitial shim layer may have a corresponding depth of about 0.2 mm or 0.3 mm or more to receive the interstitial shim layer, with the interstitial shim layer positioned within the interstitial shim cavity with an intervening space above or below it in the cavity, the space configured to receive shaped pieces of ferromagnetic or non-magnetic material.

In embodiments, removal of material from the interstitial shim layer may be combined with addition or movement of material into the interstitial shim cavity, and these modifications may further be combined with patterned removal of material from the front or rear faces of the main and/or second bodies of the pole piece assembly through manual and/or automated processes including but not limited to chemical etching, machining, scratching, die-punching, laser cutting, water-jet cutting, grinding and/or gouging.

The interstitial shim layer may be composed of any magnetic material (e.g., low carbon or other types of steel, or nickel, or Hiperco alloy). The interstitial shim layer may vary in thickness in support of tuning the magnetic field. The interstitial shim layer may cover most of the surface of the depression in the main body of the pole piece.

In embodiments, the shim insert body 104 may comprise threaded holes and corresponding threaded inserts (screws), and movement of material within the interstitial shim cavity may comprise adjusting the threaded inserts by rotating them into or out of the threaded holes. In embodiments, the shim insert body may comprise a shaped portion of another material that is the result of removing a portion of the shim insert body and replacing it with the said other material.

In further embodiments, a cut-away region (not shown) may be defined in the shim insert body of the pole piece assembly and this cut-away region may be adapted to receive a centerpiece. The centerpiece may be composed of magnetic or non-magnetic material(s), for example, aluminum, or any of a variety of ceramic or plastic materials, such as Delrin or ABS (acrylonitrile butadiene styrene) and may provide a magnetically inert portion within the shim insert body, which is composed of a magnetically permeable, ferromagnetic metal such as Hiperco. The shape of the shim insert body (and thereby the overall shape of the pole piece assembly) with the cut-away region may provide improved magnetic field homogeneity compared to a pole piece assembly not having the cut-away region in the shim insert body.

Positioning a non-magnetic centerpiece in the cut-away region of the shim insert body may allow for the high spatial density of shim insert holes in the shim insert body to continue into the cut-away region (not shown). This may allow the shimming function of the shim inserts (e.g., shim insert screws) to be more versatile than would be possible without the centerpiece. The shapes of the cut-away region and the centerpiece can be adjusted to improve the overall efficacy of the pole piece in a given magnet array or magnetic resonance device. When a pole piece is produced and implemented in a magnet array or magnetic resonance device, there may be iterations of pole piece machining required to optimize the effect of the pole piece on the homogeneity of the magnetic field generated by the magnet array. By selecting the shapes of the cut-away region and the centerpiece in advance, production time can be saved while improving the quality of the magnetic field for sample analysis.

In the present disclosure, the particular locations where material is removed from a main pole piece body, shim insert body or interstitial shim layer, or added to the interstitial shim cavity above or below the interstitial shim layer, and in what quantities the material is removed or added, may be calculated by first estimating or measuring a magnetic field configuration within a sample volume, through field mapping or numerical simulation, and then by estimating or measuring amounts of magnetic material to be added or removed from the pole piece assembly configuration to modify the overall magnetic field configuration within the sample volume.

In an embodiment, the main body, the shim insert body, and the interstitial shim layer are made of magnetically soft (magnetically permeable), ferromagnetic metals. Examples include iron, cobalt, nickel, steels, or alloys such as permendur, Hiperco, or other materials which acquire a magnetic polarization when placed in a polarizing magnetic field. Hiperco is a class of soft magnetic alloys containing cobalt and other metals.

In embodiments, pole piece assemblies may be used in pairs, with the front faces of the respective main pole piece bodies positioned so as to face (oppose) one another across a gap. It will be understood that such a gap can be established and maintained by positioning the pair of pole piece assemblies within a holding structure or framework (sometimes referred to as a positioner or positioner assembly) to form a further assembly (sometimes referred to as a central cavity assembly). Said structure or framework may hold the pole piece assemblies essentially fixed in position or, alternatively, may permit adjustments in position to be made by a user or actuator. Such adjustments can be made using one or more of a variety of actuators provided for that purpose, such as (but not limited to) screws, levers, sliders, tilting devices, goniometers, movable wedges, or the like.

In applications where pole piece assemblies are used in pairs, it may be useful to position the members of the pair so that their respective front faces are substantially parallel when in a nominal position (for example when the pair of pole piece assemblies is initially positioned or installed in a magnet array). Since in embodiments front face surfaces of main pole piece bodies are curved according to a mathematical prescription, it is useful to clarify what it means for two curved front faces to be “substantially parallel.” In this disclosure, two curved front faces are said to be substantially parallel when the reference planes defining the curvature of the respective front face surfaces are substantially parallel or coincident.

It may further be useful to define a preferred volume, which may be present in between the two pole piece assemblies, and a central, abstract geometrical feature defined with respect to said volume, such as an origin point, a coordinate system, or a plane, such as a plane that may be substantially parallel to the two front faces of the pole pieces. Again, a plane is substantially parallel to a curved front face surface if the plane is substantially parallel to the reference plane defining the curved front face surface, or coincident with said reference plane. In embodiments, this preferred volume may comprise a sample volume, which is configured to receive a sample or sample tube. In embodiments, the preferred volume may be a volume in which a user may desire to have a magnetic field that has certain preferred characteristics, such as a degree of spatial homogeneity. In that case, it may be desirable to map or estimate the said characteristics within the preferred volume.

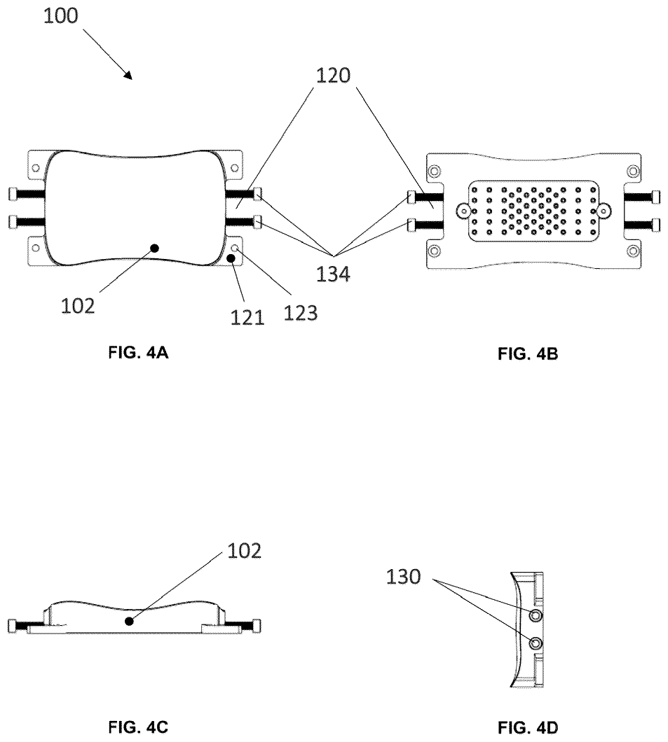

FIG. 4A, FIG. 4B, FIG. 4C and FIG. 4D are front, rear, side and end views, respectively, of pole piece assembly 100 in accordance with the embodiment of foregoing FIGS. 1A through 3B. As illustrated in FIGS. 4A and 4B, the main pole piece body 102 defines a cutout portion 120 on each of first and second ends of the main pole piece body 102. Proximate to the cutout portions 120 are mounting tabs 121 which may in embodiments comprise holes 123 or grooves or like features to accommodate fasteners, such as mounting screws.

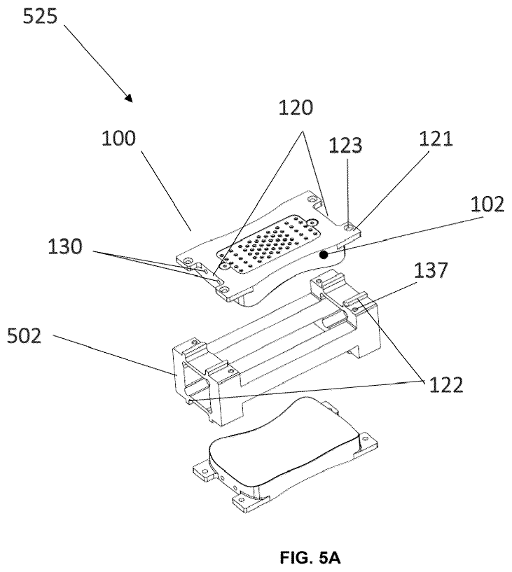

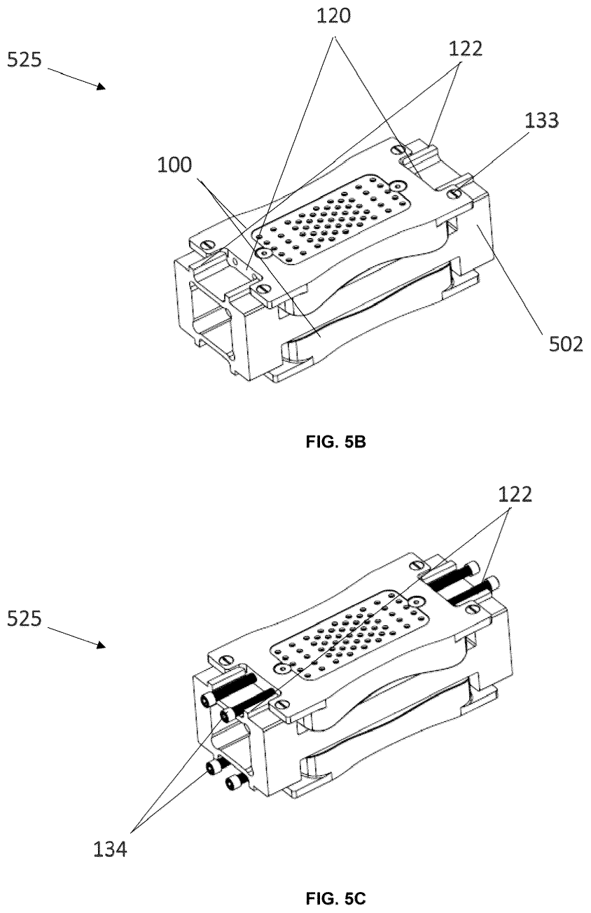

A central cavity assembly 525 including a positioner 502 is shown in FIG. 5A, FIG. 5B, and FIG. 5C. The positioner 502 has protrusions 122 which correspond to the cutout portions 120 on each of two pole piece assemblies 100. Eight protrusions 122 are shown on the positioner 502, however, only two of the eight protrusions 122 are labeled in each of FIG. 5A, FIG. 5B, and FIG. 5C. The protrusions 122 are received in (mate with) the corresponding cutout portions 120, as illustrated in FIG. 5B and FIG. 5C which show the central cavity assembly 525 in its assembled configuration. In the assembled configuration, screws 133 engage holes 123 in the mounting tabs 121 of the pole piece assemblies 100 and corresponding holes 137 in the positioner 502 to fasten the pole piece assemblies 100 to the positioner 502. The protrusions and cutout portions shown in FIGS. 5A-C are examples and, in other embodiments, may be shaped and dimensioned differently. The protrusions and cutout portions may together define a substantially flat surface when the pole piece assemblies and the positioner are assembled. In the embodiment shown in FIGS. SA-C, the positioner 502 is shown as a single piece; however, in alternative embodiments, the positioner may have multiple parts.

Although not shown in FIG. 5A and FIG. 5B, shimming rods 134 are shown in FIG. 5C (also shown in FIG. 3 and FIG. 4). In the embodiment of FIG. 5, first shimming holes 130 in the pole piece assembly 100 and protrusions 122 in the positioner 502 are oriented with respect to each other (when the pole piece assemblies 100 are assembled with the positioner 502) to allow shimming rods 134 to travel within the first shimming holes 130 and in proximity to (or guided by) protrusions 122. Adjustment of the shimming rods 134 in and/or out of the first shimming holes 130 modifies the magnetic field created by the magnet assembly into which the central cavity assembly 525 is (to be) inserted.

As shown in FIG. 3 through FIG. 5, each of the first shimming holes 130 is adapted to receive one shimming rod 134. As an alternative to the protrusions 122 on each of first and second ends of the positioner 502 (said protrusions which serve as physical guides for the shimming rods 134), second shimming holes (not shown) may instead be provided in the positioner. In such an alternative embodiment, the first shimming holes defined by the pole piece assemblies and the second shimming holes defined by the positioner are aligned with each other when one or more pole piece assemblies are assembled with the positioner to allow the shimming rods to travel (be adjusted) within the first shimming holes and the second shimming holes until a desired change in the homogeneity of the magnetic field is achieved.

Other modifications of the positioner are possible and the configuration shown in FIG. 5 is by way of illustrative example and not by way of limitation. For example, there may be fewer protrusions, such as four protrusions instead of eight, i.e, two protrusions instead of four protrusions on each of the first and second ends of the positioner. Each of the four protrusions may correspond to (mate with) one of the cutouts on the pole piece assemblies when two pole piece assemblies are assembled with the positioner into the central cavity assembly.

The positioner may be composed of one or more parts, including parts extending beyond the length of the pole piece assemblies when the pole piece assemblies are assembled with the positioner into the central cavity assembly. The positioner may have various functions depending on the magnet assembly in which the positioner and pole piece assemblies are utilized. Functions of the positioner may include, but are not limited to, (i) providing a structure for receiving the pole piece assemblies and inserting the pole piece assemblies into the central cavity assembly and into the central cavity (bore) of a magnet assembly; (ii) providing a structure through which physical adjustments can be made to set or change the position or alignment of the pole piece assemblies with respect to the positioner and the bore; (iii) securing the central cavity assembly to the magnet assembly, for instance, within the bore of the magnet assembly; and/or (iv) positioning the pole piece assemblies a defined distance from where a sample would be positioned for analysis within the bore and the magnetic field of the magnet assembly.

The embodiments of the present disclosure are not limited to the number of shimming holes, shimming rods, cutouts and protrusions shown in the Figures. In other embodiments, a single shimming hole or more than two shimming holes in each of, or either of, the first and second ends of the pole piece assembly may be used. In further embodiments, there may be an absence of shimming holes.

As shown in FIG. 3B, the shim insert body 104 of pole piece assembly 100 defines shim insert holes 140. The shim insert holes 140 are adapted to receive shim insert screws 142 to achieve a change in the homogeneity of the magnetic field. Sixty-one shim insert holes 140 are shown in the shim insert body 104 in FIG. 3B; however, fewer or more shim insert holes may be defined in the shim insert body. The present disclosure contemplates varying numbers, sizes, and patterns of shim insert holes (with corresponding shim insert screws) as applications require. FIG. 3B shows an embodiment comprising two interleaved rectangular configurations of shimming holes coincident with grids of points (one grid is 5×9 points, the other is 4×4 points, for a total of 61 points). The present disclosure includes as alternative embodiments rectangular or hexagonal or triangular grids containing varying numbers of points distributed over the surface of the shim insert body. A greater number and density of grid points yields finer control over magnetic field homogeneity at the cost of increased manufacturing complexity.

The shim insert screws may have the same lengths or different lengths and may be inserted into the shim insert holes to differing degrees to improve or optimize magnetic field homogeneity. Depending on the characteristics of the magnetic field to be shimmed, any of the shim insert holes may be occupied or unoccupied by a shim insert screw, and any particular shim insert screw that is used may be inserted to varying degrees to shim the magnetic field. Other embodiments are also contemplated for optimizing magnetic field homogeneity by inserting objects into receiving apertures/holes including, but not limited to, inserting circular/square/rectangular/irregular shaped objects into receiving holes/apertures for optimizing magnetic field homogeneity.

The magnetic field generated by one magnet array (into which pole piece assemblies are then inserted) may differ from that of another magnet array depending on the particular configuration of component magnets or mechanical or magnetic tolerances associated with the materials or manufacturing methods used in construction of the magnet arrays. There may be differences in the magnetic characteristics, material properties and/or shape of each component magnet and/or pole piece (or pole piece assembly) provided. These differences may lead to different arrangements of shim insert screws (or alternatives) in the shim insert holes (or other apertures) for improving or optimizing the magnetic fields generated by different magnet arrays.

In FIG. 3A and FIG. 3B, shim insert screws 142 are threaded and engage a cooperating reciprocal thread on the inside surface of the receiving shim insert hole 140. In embodiments such threading engagement serves to position the shim insert screw and to secure the shim insert screw into the shim insert hole. The geometry of the corresponding mating parts will be chosen to permit the necessary rotation.

In an embodiment, shim insert screws are screwed into shim insert holes in the shim insert body of the pole piece assembly substantially along an axis that is coincident with a main magnetic field that magnetically polarizes the permeable magnetic material of the pole piece (or pole piece assembly). As shown in FIG. 3A and FIG. 3B, the shim insert screws 142 in this embodiment are threaded into or out of the shim insert holes 140 along this axis, which is perpendicular to the axis along which the shimming rods 134 are threaded into or out of the first shimming holes 130 and second shimming holes 132.

For a given pole piece assembly, the shimming rods may have different lengths and/or the shim insert screws may have different lengths, allowing for different amounts of magnetic material to be positioned at different locations to improve or optimize the homogeneity of the magnetic field. The length of the shim insert screws in embodiments may range from 0.05 inches to 0.16 inches or longer as applications require.

The multipartite nature of the pole piece assemblies of embodiments of the present disclosure allows for independent physical modifications to be made to each of the discrete parts of the pole piece assembly prior to its use in applications with a positioner, magnet array, or in a magnetic resonance device. Specifically, the rear and front faces and body of the main pole piece body, the rear and front faces and body of the shim insert body, and the rear and front faces and body of the interstitial shim layer(s) can each be physically adapted so that when assembled into the pole piece assembly as a whole, the effect on the magnetic field of the magnet array is enhanced and/or refined more or with greater convenience than would be possible with a single-part pole piece (a pole piece without multiple parts).

In another aspect of the disclosure, the presence, absence, and positions of shim insert screws 142 within the shim insert body 104 and the exact functional content of the depth-function

$$z ( x , y ) = {\sum }_{i , j}^{□} {c}_{i j} {f}_{i} ( x ) {g}_{j} ( y ) ,$$

(particularly the coefficients cᵢⱼ relative to chosen basis-function sets Ωₓ and Ω_{y}) can be chosen by physically adapting the shim insert screws accordingly and the shape of the front face surface.

Said physical adaptation can include removal of ferromagnetic material using any subtractive process, such as (but not limited to) chemical etching, machining, scratching, die-punching, laser cutting, water-jet cutting, drilling, tapping, grinding and/or gouging. Said removal may be followed by replacement of the removed material with a non-magnetic material of the same or similar shape for maintaining the strength of the pole piece part, which might otherwise be compromised in the absence of the replacement material. The replaced, shaped material may also serve the purpose of continuing a pattern of depressions, threaded holes, or other features in the pole piece part, which would not be possible if the removed magnetic material were not replaced with the non-magnetic material. Moreover, each of these independent modifications may be combined with a further independent modification, which is the insertion of shaped pieces of magnetic material into the interstitial shim cavity above or below the interstitial shim layer(s), into the main pole piece body, and/or into the shim insert body of the pole piece (or pole piece assembly).

In an embodiment, a magnetic field in a preferred volume may have several functional components of magnetic field inhomogeneity, that is, several individual gradients. In the present disclosure, the plurality of regions (the rear and front faces and body of the one or more interstitial shim layers, the rear and front faces of the main pole piece body, the rear and front faces of the shim insert body, and the spaces below and/or above the interstitial shim layer(s) within the interstitial shim cavity), wherein magnetic material can be removed or added to suppress multiple inhomogeneities of magnetic field within the preferred volume. In particular, different gradients can be addressed through modification of different ones of the plurality of regions.

As described in this disclosure, the choice of the dimensions, material, and location on the interstitial shim layer of material removed and/or added is determined based on an understanding of the magnetic field gradients generated by a magnet array. Adding and removing material with respect to the interstitial shim layer, main pole piece body and shim insert body in a pole piece assembly allows for selective improvement of magnetic field inhomogeneities generated by different magnetic field gradients. In applications, improving, suppressing, adjusting, modifying, or shimming the magnetic field may lead to improved performance of magnetic resonance devices comprising the magnet array and pole piece assemblies for magnetic resonance sample analysis. Such improvement may include rendering the magnetic field more homogeneous in the sample volume.

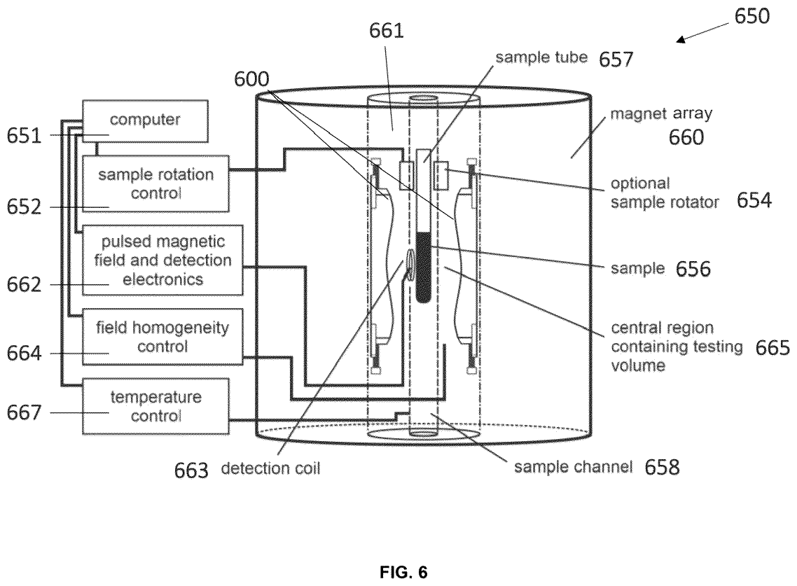

In embodiments of this disclosure, the magnet array may be comprised in a magnetic resonance apparatus or device. For example, FIG. 6 is an exemplary block diagram of a magnetic resonance device 650 in accordance with an embodiment of the disclosure. Two pole piece assemblies 600 are shown schematically in FIG. 6 positioned in a magnet array 660, the magnet array having a central cavity 661 (sometimes referred to as a bore of the magnet array). The device 650 further comprises a computer 651 operably connected to a sample rotation control module 652 for controlling rotation of an optional sample rotator 654 used for rotating a sample 656 in a sample tube 657 within a sample channel 658 provided in the magnet array 660.

The computer 651 may also be operably connected to a pulsed magnetic field control and signal detection electronics module 662 used for controlling a detection coil 663 and receiving signal therefrom. The device 650 may also include a field homogeneity control module 664 for controlling the magnetic field in a centrally located testing volume 665. A temperature control module 667 may also be provided for controlling the temperature of the magnet array 660 and the temperature inside the channel 658. In embodiments, the pole piece assemblies 600 are supported (assembled with) a positioner to yield a central cavity assembly; however, the positioner and central cavity assembly are excluded from in FIG. 6 for clarity of illustration.

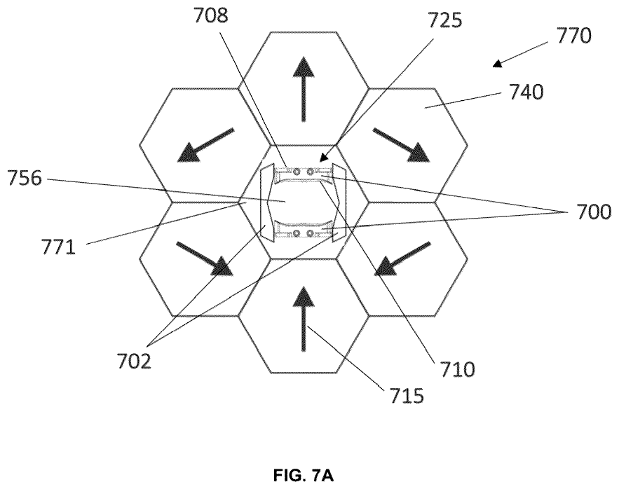

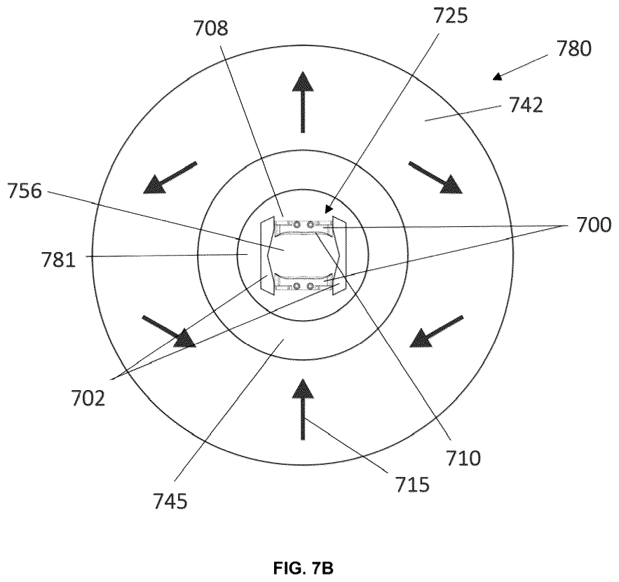

FIG. 7A is a cross-sectional view of a magnet array (assembly) 770 including two pole piece assemblies 700. FIG. 7A provides an example of how pole piece assemblies of the present disclosure may be positioned in an assembly (array) of magnets which may be configured for use in a magnetic resonance device (for example, the embodiment depicted in FIG. 6).

It will be seen in the cross-sectional view of FIG. 7A that two pole piece assemblies 700, each having a rear face 708 and a front face 710, are disposed within a central cavity 771 of a hexagonal Halbach cylinder, Halbach-type or other magnet array 770. The pole piece assemblies are supported by positioner 702 such that together the pole piece assemblies and positioner form a central cavity assembly 725. A central sample volume or sample space 756 (sometimes referred to as a central region containing a sample testing volume) for analysis is shown in the central cavity and positioned between the two pole piece assemblies 700. In the embodiment shown in FIG. 7A, magnet array 770 comprises six individual magnets 740, as shown, each having an individual magnetization direction 715. In alternative embodiments, the six magnets shown are the central six magnets in a larger assembly comprising additional magnets.

A more general embodiment is shown in cross-sectional FIG. 7B of magnet array 780, which comprises a Halbach cylinder, Halbach-type, or other magnet array portion 742, and an expanded interior portion 745 relative to the central cavity 771 of FIG. 7A. The expanded interior portion 745 may contain magnetic and non-magnetic structures around a central cavity 781. As will be seen in both FIGS. 7A and 7B, the front face 710 of the main pole piece body of each pole piece assembly 700 is proximal to the central sample volume or sample space 756 and the rear face 708 of the main pole piece body of each pole piece assembly 700 is proximal to the interior surface of the central cavity 781 defined by the magnet array 780 (in FIG. 7B, or 770 in FIG. 7A). Pole piece assemblies 700 are assembled with positioner 702 to form a central cavity assembly 725 within the central cavity 781. In alternative embodiments the pole pieces (or pole piece assemblies) may be in accordance with any other embodiments of the subject matter hereof.

In embodiments, shimming rods 134 may be up to 1.5 inches in length or longer as applications to adjust the magnetic field require. Although a pole piece assembly may have additional shimming holes and shimming rods, in the non-limiting examples depicted in FIGS. 1A-5C, up to four shimming rods are inserted into the shimming holes of one pole piece assembly; thus, up to eight shimming rods may be used in a magnetic resonance device having two pole piece assemblies (e.g., as shown in FIG. 6). The maximum length of the shimming rods may be shorter or longer depending on the type and size of the magnet array or magnetic resonance device incorporating the pole pieces.

When deciding on pole piece assembly characteristics (including but not limited to shape, composition, size, number of parts) useful or desirable in applications, even small variations in pole pieces that are in close proximity to the sample in a magnetic resonance device can have significant effects on the magnetic field homogeneity and on results from a sample analysis. Pole piece manufacturing and adjustment to improve or optimize magnetic field homogeneity and provide predictable and scalable production of magnet arrays comprising pole piece assemblies requires that one or more magnetic field inhomogeneities be identified by:
simulating the magnetic field generated by the magnet array, including or excluding contributions from a pole piece assembly;
measuring the magnetic field generated by the magnet array, including or excluding contributions from a pole piece assembly using a field mapping device; or
a combination thereof.

Disclosed herein is a method for shimming a magnetic field generated by a Halbach-type magnet configuration. The method, which may be iterative, comprises:
providing a pole piece assembly, the pole piece assembly comprising a main pole piece body having a front face and a rear face; a shim insert body having a front face and a rear face, the shim insert body being adapted to receive and/or be received by the main pole piece body to form an assembled pole piece assembly such that the rear face of the main pole piece body faces the front face of the shim insert body; a depression formed in at least one of: the rear face of the main pole piece body and the front face of the shim insert body, such that an interstitial shim cavity is formed by the depression when the main pole piece body and the shim insert body are in an assembled position; and an interstitial shim layer provided in the interstitial shim cavity;
identifying a magnetic field inhomogeneity generated by a magnetic field gradient by simulating or measuring (using a field mapping device/equipment) the magnetic field generated by the Halbach-type magnet configuration;
modifying a material content of the interstitial shim cavity by one or more of: removing material from the interstitial shim layer, adding material above or underneath the interstitial shim layer in the interstitial shim cavity, and moving material within the interstitial shim layer; and
inserting the pole piece assembly into a central cavity of the Halbach-type magnet configuration for shimming the magnetic field generated by the Halbach-type magnet configuration to improve the magnetic field homogeneity.

The method may further comprise:
identifying one or more additional magnetic field inhomogeneities generated by one or more additional magnetic field gradients, respectively; and
repeating any of the foregoing steps until the magnetic field homogeneity reaches a desirable level allowing for sample analysis.

The desirable level of magnetic field homogeneity can be determined by comparing measured values of field deviation using a magnetic field mapping device/equipment or by observing the characteristics of a magnetic resonance signal (such as line width or decay time) obtained from a test sample placed inside the magnet configuration.

Disclosed herein is a method for shimming a magnetic field generated by a Halbach-type magnet configuration, the magnet configuration at least partly enclosing a sample volume. The method comprises:
identifying a magnetic field inhomogeneity in the sample volume of the Halbach-type magnet configuration, the inhomogeneity being generated by a magnetic field gradient;
providing a pole piece assembly, the pole piece assembly comprising a main pole piece body, a shim insert body, and an interstitial shim layer, the main pole piece body comprising a curved front face surface;
forming a modified pole piece assembly by performing one or more of: removing material from, adding material to, moving material within at least one part of the pole piece assembly based on the identified magnetic field inhomogeneity; and
inserting the modified pole piece assembly into the Halbach magnet array to shim the magnetic field.

The method may further comprise:
identifying one or more additional magnetic field inhomogeneities generated by one or more additional magnetic field gradients, respectively; and
repeating any of the foregoing steps for each of the one or more additional magnetic field inhomogeneities.

The method may further comprise identifying the magnetic field inhomogeneity by:
simulating a magnetic field generated by the Halbach-type magnet configuration; or
measuring a magnetic field generated by the Halbach-type magnet configuration using a magnetic field mapping device.

The step of moving material within at least one part of the pole piece assembly may comprise:
adjusting a position of at least one shimming rod in at least one first or second shimming hole defined by the main pole piece body or positioner, respectively;
adjusting a position of at least one shim insert screw in at least one shim insert hole defined within the shim insert body; or
a combination thereof.

The method may further comprise assembling two modified pole piece assemblies and a positioner into a central cavity assembly prior to inserting the two modified pole piece assemblies into the Halbach-type magnet configuration.

In a further aspect of the disclosure, disclosed herein is a method for shimming a magnetic field generated by a Halbach-type magnet configuration, the magnet configuration at least partly enclosing a sample volume. The method comprises:
identifying a magnetic field inhomogeneity in the sample volume of the Halbach-type magnet configuration, the inhomogeneity being generated by a magnetic field gradient;
providing a pole piece assembly, the pole piece assembly comprising a main pole piece body, the main pole piece body comprising:
a curved front face surface S;
a reference plane, P, containing an origin point, O);
a cartesian reference frame, fixed at O, comprising length, width, and height axes, \hat{x}, ŷ, and \hat{z}, respectively, and corresponding cartesian coordinates x, y, and z;
a rectangular region, R, having length, l, and width, w, lying in reference plane P and centered at origin point O, the rectangular region having sides parallel to the x and y axes of the cartesian reference frame and containing points having cartesian coordinates (x, y) satisfying

$$x \leq + \frac{1}{2} l and - \frac{1}{2} w \leq y \leq + \frac{1}{2} w ,$$

wherein points lying on the front face surface S are described by a smooth depth-function z(x, y) of the cartesian coordinates, defined on R, the depth-function quantifying the perpendicular distance, z, from R to the corresponding point on S,
and wherein the depth-function takes the form

$$z ( x , y ) = {\sum }_{i , j}^{□} {c}_{i j} {f}_{i} ( x ) {g}_{j} ( y ) ,$$

where functions fᵢ and gⱼ are smooth basis functions selected from basis-function sets Ωₓ and Ω_{y}, and where cᵢⱼ are expansion coefficients.
forming a modified main pole piece body by performing one or more of: removing material from, or adding material to the main pole piece body based on the identified magnetic field inhomogeneity; and
inserting a modified pole piece assembly comprising the modified main pole piece body into the Halbach-type magnet configuration to shim the magnetic field.

The method may further comprise:
identifying one or more additional magnetic field inhomogeneities generated by one or more additional magnetic field gradients, respectively; and
repeating any of the foregoing steps for each of the one or more additional magnetic field inhomogeneities.

The method may further comprise identifying the magnetic field inhomogeneity by:
simulating a magnetic field generated by modifying the front face surface of the main pole piece body by modulating (adjusting) the coefficients cᵢⱼ in the depth-function defining the front face surface S; or
measuring a magnetic field generated by modifying the front face surface of the main pole piece body according to modulations (adjustments) of the coefficients cᵢⱼ in the depth-function defining the front face surface S and using a magnetic field mapping device to record changes in field configuration corresponding to said adjustments.

In the foregoing disclosure of methods (and associated disclosure of mathematical configurations of the front face surface of the main pole piece body), a depth-function z(x, y) is defined for the front face surface of a main pole piece body, the depth-function taking the form z(x, y)=Σ_{i,j}^{□}cᵢⱼfᵢ(x)gⱼ(y), where functions fᵢ and gⱼ are smooth basis functions selected from basis-function sets Ωₓ and Ω_{y}, and where cᵢⱼ are expansion coefficients. Implementing the disclosed main pole piece body and shimming methods, accordingly, comprises selecting appropriate basis-function sets Ωₓ and Ω_{y}. In a desirable basis-function set, the individual functions are differentiable and in embodiments are smooth. In embodiments, examples of basis functions are: orthogonal polynomials, including Jacobi polynomials, Legendre polynomials, Laguerre polynomials, Chebyshev polynomials, hypergeometric functions, trigonometric functions, inverse trigonometric functions, hyperbolic functions, inverse hyperbolic functions, Bessel functions, Gaussian functions, rational functions, Pade approximants, and associated Legendre functions, in non-limiting examples. The disclosure also contemplates use of scaled sums, products, quotients, and compositions of the foregoing types of functions. A user may select a basis-function set according to needs of an application, and, in embodiments, according to simulations of magnetic field changes associated with changes to a front face surface induced by varying corresponding expansion coefficients.

As described above, in an embodiment of the present disclosure, the pole piece assemblies are attached to a positioner to form a central cavity assembly. The positioner positions, for example, two pole piece assemblies in a suitable arrangement for direct installation or implementation in the central cavity of a magnet array. In exemplary embodiments, the two pole piece assemblies are positioned with the front faces of their respective main pole piece bodies facing each other across a volume of space that contains a sample volume, parallel to each other, with their front faces (more precisely, the reference planes used to mathematically define their front face surfaces) substantially perpendicular to a main static magnetic field provided by the magnet array. In embodiments, a pole piece assembly extends the entire length of the magnet array or the central cavity therein. In alternative embodiments the pole piece assembly extends for a distance that is longer than the magnet array or cavity therein. In other embodiments, a pole piece assembly extends only a fraction of the length of the cavity or magnet array.

While preferred embodiments have been described above and illustrated in the accompanying drawings, it will be evident to those skilled in the art that modifications may be made without departing from this disclosure. Such modifications are considered as possible variants comprised in the scope of the disclosure.

1. A pole piece assembly for use in a Halbach-type magnet configuration, the pole piece assembly comprising a rear face, a front face S, and ends separated by a first distance defining a length of said pole piece assembly along a first axis extending between said ends, said pole piece assembly being configured for insertion into an interior of the Halbach-type magnet configuration along said first axis, wherein a surface of the front face S is curved, and wherein a curvature of the front face is mathematically defined for shimming the magnetic field generated by the magnet configuration.

2. The pole piece assembly of claim 1, wherein the pole piece assembly is elongated in shape along the first axis.

3. The pole piece assembly of claim 1, further comprising:
a reference plane, P, containing an origin point, O, the reference plane being in a three-dimensional volume occupied by and surrounding the pole piece assembly;
a cartesian reference frame, fixed at O, comprising length, width, and height axes (\hat{x}, ŷ, and \hat{z}), and corresponding Cartesian coordinates x, y, and z respectively along said axes; and
a rectangular region, R, having length, l, and width, w, lying in reference plane P and centered at origin point O, the rectangular region having sides parallel to the x and y axes of the cartesian reference frame and containing points having cartesian coordinates (x, y) satisfying
$$- \frac{1}{2} l \leq x \leq + \frac{1}{2} l and - \frac{1}{2} w \leq y \leq + \frac{1}{2} w ;$$
wherein points lying on the front face surface S are described by a smooth depth-function z(x, y) of the cartesian coordinates, defined on R, the depth-function quantifying the perpendicular distance, z, from R to the corresponding point on S; and
wherein the depth-function takes the form z(x,y)=Σ_{i,j}cᵢⱼfᵢ(x)gⱼ(y), where functions fᵢ and gⱼ are smooth basis functions selected from basis-function sets Ωₓ and Ω_{y}, and where cᵢⱼ are expansion coefficients.

4. The pole piece assembly of claim 3, wherein the reference plane, P, is coincident with a physical flat surface on a body of the pole piece assembly.

5. The pole piece assembly of claim 3, wherein the reference plane, P, is an abstract plane in the three-dimensional volume occupied by and surrounding the pole piece assembly.

6. The pole piece assembly of claim 1, wherein a main body of said pole piece assembly is made of a magnetically permeable material.

7. The pole piece assembly of claim 1, wherein a main body of said pole piece assembly acquires a magnetic polarization when placed in a magnetic field.

8. The pole piece assembly of claim 3; wherein said basis-function sets Ωₓ and Ω_{y} are sets of orthogonal polynomials, Jacobi polynomials, Legendre polynomials, Laguerre polynomials, Chebyshev polynomials, hypergeometric functions, trigonometric functions, inverse trigonometric functions, hyperbolic functions, inverse hyperbolic functions, Bessel functions, Gaussian functions, rational functions, Pade approximants, or associated Legendre functions or are scaled sums, products, quotients, or compositions thereof.

9. The pole piece assembly of claim 1, further comprising a shimming hole adapted to accept the insertion thereinto of at least one cooperating shimming rod.

10. The pole piece assembly of claim 9, wherein the shimming hole comprises a female screw thread and said shimming rod comprises a cooperating male screw thread so that the shimming rod can be screwed into the pole piece assembly.

11. The pole piece assembly of claim 1, comprising:
a main pole piece body having a front face and a rear face;
a shim insert body having a front face and a rear face, the shim insert body being adapted to receive and/or be received by the main pole piece body to form the pole piece assembly such that the rear face of the main pole piece body faces the front face of the shim insert body when in an assembled position;
a depression formed in at least one of: the rear face of the main pole piece body and the front face of the shim insert body, such that an interstitial shim cavity is formed by the depression when the main pole piece body and the shim insert body are in an assembled position; and
an interstitial shim layer provided in the interstitial shim cavity.

12. The pole piece assembly of claim 11, wherein the shim insert body defines shim insert holes adapted to accept the insertion thereinto of one or more shim inserts.

13. The pole piece assembly of claim 12, wherein said one or more shim inserts are threaded and engage a cooperating reciprocal thread on the inside surface of the receiving shim insert holes so that the shim inserts can be screwed into the pole piece assembly.

14. The pole piece assembly of claim 11, wherein a depth of the depression is greater than a thickness of the interstitial shim layer to allow for insertion of a material having the same or different magnetic properties above or underneath the interstitial shim layer for shimming the magnetic field generated by the Halbach-type magnet configuration.

15. A magnetic resonance device comprising the pole piece assembly of claim 1.

16. A method for shimming a magnetic field generated by a Halbach-type magnet configuration, the magnet configuration at least partly enclosing a sample volume, the method comprising:
identifying a magnetic field inhomogeneity in the sample volume of the Halbach-type magnet configuration, the inhomogeneity being generated by a magnetic field gradient;
providing a pole piece assembly, the pole piece assembly comprising a main pole piece body, the main pole piece body comprising:
a curved front face surface S;
a reference plane, P, containing an origin point, O;
a cartesian reference frame, fixed at O, comprising length, width, and height axes, \hat{x}, ŷ, and \hat{z}, respectively, and corresponding cartesian coordinates x, y, and z;
a rectangular region, R, having length, l, and width, w, lying in reference plane P and centered at origin point O, the rectangular region having sides parallel to the x and y axes of the cartesian reference frame and containing points having cartesian coordinates (x, y) satisfying
$$- \frac{1}{2} l \leq x \leq + \frac{1}{2} l and - \frac{1}{2} w \leq y \leq + \frac{1}{2} w ,$$
wherein points lying on the front face surface S are described by a smooth depth-function z(x, y) of the cartesian coordinates, defined on R, the depth-function quantifying the perpendicular distance, z, from R to the corresponding point on S; and
wherein the depth-function takes the form z(x,y)=Σ_{i,j}cᵢⱼfᵢ(x)gⱼ(y), where functions fᵢ and gⱼ are smooth basis functions selected from basis-function sets Ωₓ and Ω_{y}, and where cᵢⱼ are expansion coefficients;
forming a modified main pole piece body by performing one or more of:
removing material from, or adding material to the main pole piece body based on the identified magnetic field inhomogeneity; and
inserting a modified pole piece assembly comprising the modified main pole piece body into the Halbach-type magnet configuration to shim the magnetic field.

17. The method of claim 16, further comprising:
identifying one or more additional magnetic field inhomogeneities generated by one or more additional magnetic field gradients; and
repeating the steps of identifying to inserting for each of the one or more additional magnetic field inhomogeneities.

18. The method of claim 16, further comprising identifying the magnetic field inhomogeneity by simulating a magnetic field generated by modifying the front face surface of the main pole piece body by adjusting the coefficients ci in the depth-function defining the front face surface S.

19. The method of claim 16, further comprising identifying the magnetic field inhomogeneity by measuring a magnetic field generated by modifying the front face surface of the main pole piece body according to adjustments of the coefficients cᵢⱼ in the depth-function defining the front face surface S and using a magnetic field mapping device to record changes in field configuration corresponding to said adjustments.

20. The method of claim 16, wherein said basis-function sets Ωₓ and Ω_{y} are sets of orthogonal polynomials, Jacobi polynomials, Legendre polynomials, Laguerre polynomials, Chebyshev polynomials, hypergeometric functions, trigonometric functions, inverse trigonometric functions, hyperbolic functions, inverse hyperbolic functions, Bessel functions, Gaussian functions, rational functions, Pade approximants, or associated Legendre functions or are scaled sums, products, quotients, or compositions thereof.

21. The method of claim 16, further comprising assembling two modified pole piece assemblies and a positioner into a central cavity assembly prior to inserting the two modified pole piece assemblies into the Halbach-type magnet configuration.
